(19) United States
(12) Patent Application Publication
(10) Pub. No.: US 2010/0248155 A1
(43) Pub. Date: Sep. 30, 2010

(54) Illumination Control Module, and Diffraction Illumination System and Photolithography System Including the Same, and Methods of Fabricating Semiconductors Using the Same

(75) Inventors: Woo-Seok Shim, Osan-si (KR); Yong-Jin Chun, Daejeon (KR); Suk-Joo Lee, Yougin-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/730,707

(22) Filed: Mar. 24, 2010

(30) Foreign Application Priority Data
Mar. 31, 2009 (KR) 10-2009-0027623

(51) Int. Cl. G03F 7/20

(52) U.S. Cl. 430/319

(57) ABSTRACT

An illumination control module, which enables one diffraction optical element (DOE) to be applied to various photolithography processes, and a diffraction illumination system and a photolithography system including the same are provided. The illumination control module includes a convex-ring-shaped upper lens, and a concave-ring-shaped lower lens.

### PRIORITY STATEMENT

This application claims the benefit of priority under 35 U.S.C. §119 from Korean Patent Application No. 10-2009-0027623, filed on Mar. 31, 2009, the contents of which are hereby incorporated herein by reference in their entirety.

### BACKGROUND

1. Field

Some example embodiments relate to an illumination control module capable of controlling an illumination angle and region of light and a photolithography system.

2. Description of Related Art

In photolithography technology for manufacturing semiconductor devices, an off-axis illumination technique has been developed to obtain high resolution. In the off-axis illumination technique, light is projected where an incident angle of the light is obliquely set. Accordingly, apertures having various forms for the projection have been used. However, when the apertures are used to implement the off-axis illumination technology, only some of the total intensity of light is used for the illumination, and the rest is not used. That is, low luminous efficiency decreases productivity. In order to compensate for this, a diffractive optical element (DOE) has been proposed. The DOE is a device using holographic technology. When light is first irradiated onto a DOE having an aperture formed in a diffracted shape, the light is inversely diffracted to form an aperture shape. This technique has a higher light efficiency than in a case in which an aperture is used. However, since the shape of the DOE is fixed, an illumination angle or region cannot be adjusted in a photolithography process. Therefore, the DOE is not used in various photolithography processes.

### SUMMARY

Certain example embodiments provide an illumination control module, a diffraction illumination system and a photolithography system including an illumination control module.

Some example embodiments are directed to methods of fabricating a semiconductor using an illumination control module, a diffraction illumination system and/or a photolithography system.

Some example embodiments are directed to an illumination control module including a convex-ring-shaped upper lens and a concave-ring-shaped lower lens.

Certain other example embodiments are directed to a diffraction illumination system including a DOE and an illumination control module. The illumination control module includes a convex-ring-shaped upper lens and a concave-ring-shaped lower lens.

Other example embodiments are directed to a photolithography system including a light source, a DOE, an illumination control module, a condenser lens, a photomask stage, a relay lens, and a wafer stage. The illumination control module includes a convex-ring-shaped upper lens and a concave-ring-shaped lower lens.

Still other example embodiments are directed to a method of fabricating a semiconductor, comprising, loading a wafer into a photolithography system, the wafer having a material layer and a photoresist layer thereon, irradiating the photoresist layer using UV light, developing the photoresist layer to form a photoresist pattern, patterning the material layer to form a material pattern using the photoresist pattern as patterning mask, removing the photoresist pattern, and cleaning the wafer, wherein the photolithography system comprises a convex-ring-shaped upper lens, and a concave-ring-shaped lower lens.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a schematic view of an illumination control module according to an example embodiment.

FIGS. 2 to 4 are diagrams for illustrating the propagation of light at end surfaces indicated by dotted lines of upper and lower lenses of the illumination control module shown in FIG. 1.

FIGS. 5A and 5B are diagrams conceptually illustrating illumination control modules according to some application example embodiments.

FIG. 6 is a diagram schematically illustrating a diffraction illumination system and changes in beam shapes according to an example embodiment.

FIG. 7 is a schematic view of a photolithography system according to an example embodiment.

FIGS. 8A and 8B illustrate beam shapes converted by the illumination control modules according to various example embodiments.

FIG. 9 is a flow chart illustrating steps of fabricating a semiconductor.

FIGS. 10A to 10D illustrate exemplary processes of fabricating a semiconductor.

### DETAILED DESCRIPTION OF THE EMBODIMENTS

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, these elements should not be limited by these terms. These terms are only used to distinguish one element from another. Thus, a first element could be termed a second element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. The inventive concept, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the inventive concept. Like numbers refer to like elements throughout the description of the figures.

In this specification, a diffractive optical element (DOE) includes the concept of a holographic optical element (HOE), because the basic principle of the DOE is identical. That is, illumination control modules according to various example embodiments may be applied not only to the DOE but also to the HOE. An aperture shape used in an off-axis illumination technology using a DOE is implemented using inverse diffraction of light. The DOE can implement a beam shape the same as the aperture shape used in the off-axis illumination technology. Since the DOE has a fixed shape, it may not satisfy the requirements of various photolithography techniques. In the case of the DOE, various beam shapes are demanded depending on the types, sizes, and dispositions of patterns which are to be formed. Since the DOE is manufactured in accordance with one kind of pattern, its use for a photolithography process of forming a differently shaped pattern may be limited. Further, when a small modification is required for the same process or various process splits need to be performed, a proper DOE should be input for each process, and the process should be set up. Since such a process split is unstable and requires considerable human resources and time, the process split is difficult to perform. Accordingly, the present inventors propose an apparatus and method which can apply a DOE having one kind of beam shape into various patterns and can change a process in an analog manner.

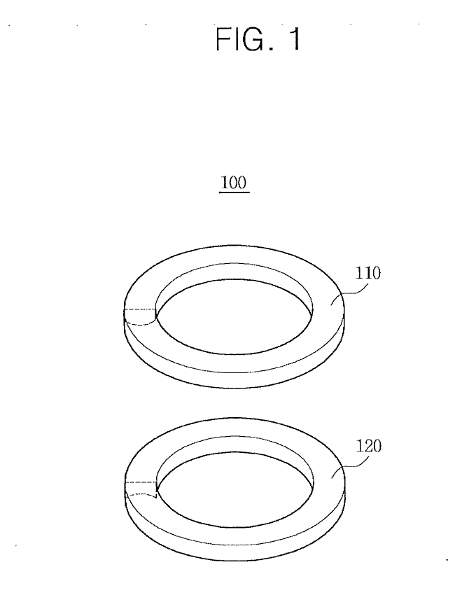

FIG. 1 is a schematic view of an illumination control module according to an example embodiment. Referring to FIG. 1, the illumination control module 100 according to this example embodiment includes a convex-ring-shaped upper lens 110 and a concave-ring-shaped lower lens 120. The upper and lower lenses 110 and 120 may have flat upper surfaces, respectively. In one embodiment, the upper lens 110 may have a convex lower surface, and the lower lens 120 may have a concave lower surface, respectively. However, the shapes of the surfaces are not limited thereto. That is, the lower surfaces of the upper and lower lenses 110 and 120 may be flattened. Lenses are classified into convex lenses and concave lenses depending on the focal distances, see Claim 1. Therefore, the functional structure of the inventive concept is not limited by the external shapes of the lenses. The upper lens 110 may move vertically. The lower lens 120 may move vertically. Specifically, in some embodiments only one of the upper and lower lenses 110 and 120 may move vertically, or both of the upper and lower lenses 110 and 120 may move vertically. The width, thickness, shape, and focal distance of the upper lens 110 may be set in an arbitrary manner. Further, the width, thickness, shape, and focal distance of the lower lens 120 may also be set in an arbitrary manner. Light is irradiated from the upper side to pass through the illumination control module 100 according to an example embodiment and is then emitted to the lower side. The upper and lower lenses 110 and 120 may have the same circumference and the same circular constant. Alternatively, the horizontal sectional width of the upper lens 110 may be larger than that of the lower lens 120.

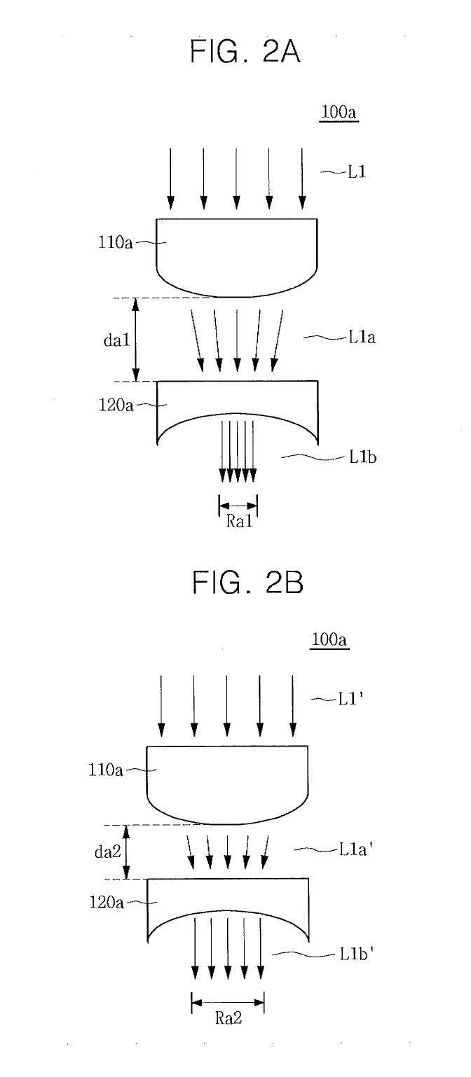

FIGS. 2 to 4 are diagrams for illustrating the propagation of light at end surfaces indicated by dotted lines of the upper and lower lenses 110 and 120 of the illumination control module 100 shown in FIG. 1. The drawings schematically illustrate the propagation directions L1, L1a, L1b, L1′, L1a′, and L1b′ of light depending on the distances da1 and da2 between the upper and lower lenses 110 and 120 and changes in the focal distances of the upper and lower lenses 110 and 120. First, referring to FIGS. 2A and 2B, light is incident in directions L1 and L1′ perpendicular to the upper surface of an upper lens 110a. Since the upper lens 110a is a convex lens, the light having passed through the upper lens 110a is propagated in directions L1a and L1a′ in which the lights are focused, and are then incident on the upper surface of the lower lens 120a. Since the lower lens 120a is a concave lens, the light having passed through the lower lens 120a is propagated in directions L1b and L1b′ in which the lights are dispersed. In this example embodiment, it is assumed that the absolute value of the focal distance of the upper lens 110a is equal to that of the lower lens 120a. Therefore, the propagation directions L1b and L1b′ of the final light will be a straight direction. The propagation directions L1b and L1b′ and illumination regions Ra1 and Ra2 of the final lights may be adjusted by the distances da1 and da2 between the upper and lower lenses 110a and 120a. As shown in FIG. 2A, when the upper and lower lenses 110a and 120a are disposed with the relatively large distance da1 provided therebetween, a narrow illumination region Ra1 may be formed. As shown in FIG. 2B, when the upper and lower lenses 110a and 120a are disposed with the relatively small distance da2 provided therebetween, a wide illumination region Ra2 may be formed. The illumination regions Ra1 and Ra2 can define a region onto which the shape of beam irradiated from a DOE is transferred. More detailed descriptions will be made below. The illumination control module 100a according to example embodiments may include a zoom function.

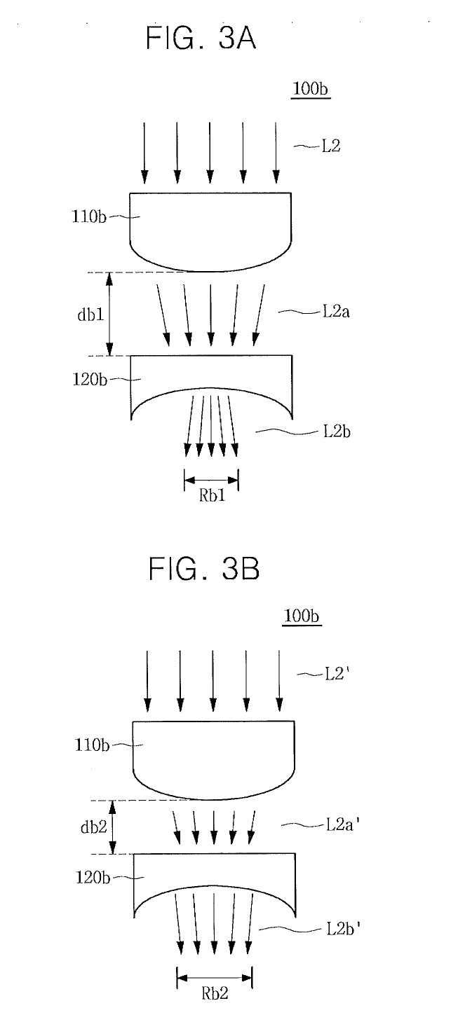

Referring to FIGS. 3A and 3B, light is incident in directions L2 and L2′ perpendicular to the upper surface of an upper lens 110b. Since the upper lens 110b is a convex lens, the light passing through the upper lens 110b propagates in directions L2a and L2a′ in which the light is focused, and is then incident on the upper surface of a lower lens 120b. Since the lower lens 120b is a concave lens, the light passing through the lower lens 120b propagates in directions L2b and L2b′ in which the light is dispersed. In this example embodiment, it is assumed that the absolute value of the focal distance of the lower lens 120b is greater than that of the upper lens 110b. Therefore, the final propagation directions L2b and L2b′ of the light may be a direction in which the light is dispersed, compared with the first propagation directions L2 and L2′ of the lights. In this example embodiment, it has been assumed that the first incident angles L2 and L2′ of the lights are perpendicular to the upper surface of the upper lens 110b. Since the relative sizes of illumination regions Rb1 and Rb2 may differ depending on distances between the lower lens 120b and a structure formed under the lower lens 120b, the two illumination regions Rb1 and Rb2 can vary widely.

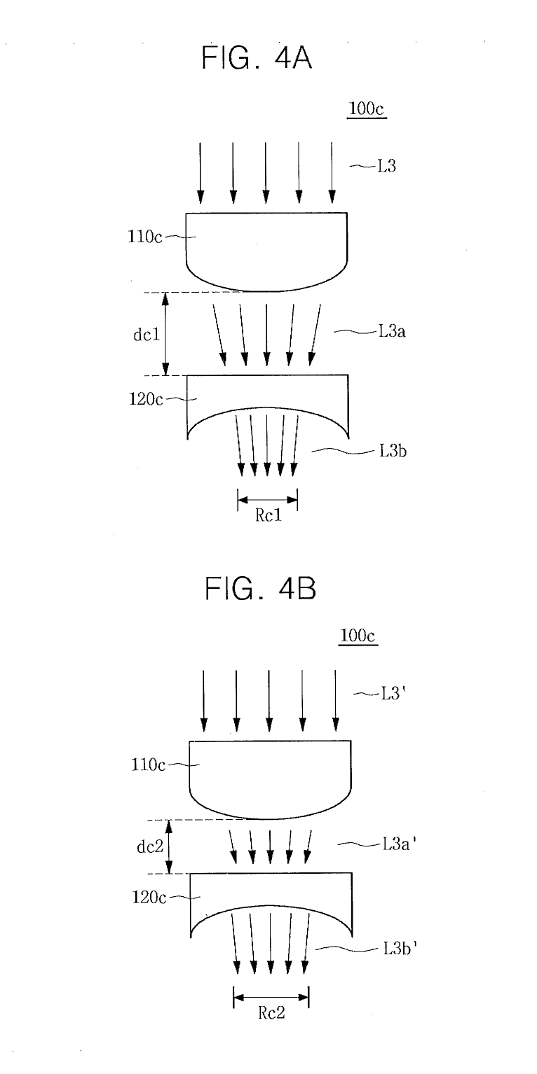

Referring to FIGS. 4A and 4B, light is incident in directions L3 and L3′ perpendicular to the upper surface of an upper lens 110c. Since the upper lens 110c is a convex lens, light having passed through the upper lens 110c propagates in directions L3a and L3a′ in which the light is focused, and are then incident on the upper surface of a lower lens 120c. Since the lower lens 120c is a concave lens, the light having passed through the lower lens 120c propagates in directions L3b and L3b′ in which the light is dispersed. In this example embodiment, it is assumed that the absolute value of the focal distance of the upper lens 110c is greater than that of the lower lens 120c. Therefore, the final propagation directions L3b and L3b′ of the light may be a direction in which the light is focused, compared with the first propagation directions L3 and L3′ of the lights. The relative sizes of illumination regions Rc1 and Rc2 may differ depending on distances between the lower lens 120c and a structure formed under the lower lens 120c. If the structure is disposed at a position closer or more distant than the combined focal distance of the illumination control module 100c, the sizes of the illumination regions Rc1 and Rc2 may differ from each other.

The illumination control modules according to various example embodiments shown in FIGS. 2 to 4 may determine emission directions (angles) of light depending on relative differences among the focal distances thereof. Further, when a distance between the lower lens 120a, 120b, or 120c and a structure formed under the lower lens is known, it is possible to adjust the sizes of the respective illumination regions.

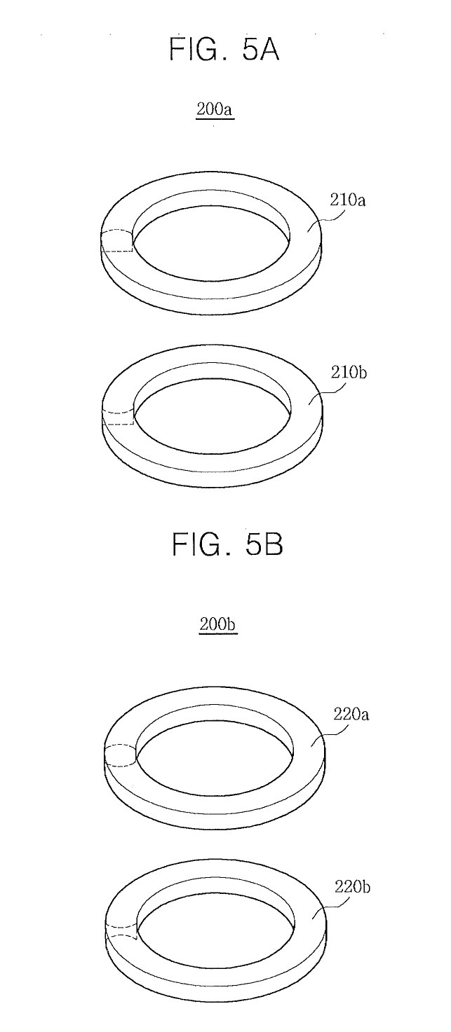

FIGS. 5A and 5B are diagrams conceptually illustrating illumination control modules according to additional examples of embodiments. Referring to FIG. 5A, the illumination control module 200a according to an application embodiment includes a convex-ring-shaped upper lens 210a and a concave-ring-shaped lower lens 210b, and the upper and lower lenses 210a and 210b may have flat lower surfaces. The upper lens 210a may have a convex upper surface, and the lower lens 210b may have a concave upper surface.

Referring to FIG. 5B, the illumination control module 200b according to another application example embodiment includes a convex-ring-shaped upper lens 220a and a concave-ring-shaped lower lens 220b. The upper lens 220a may have convex upper and lower surfaces, and the lower lens 220b may have concave upper and lower surfaces.

The upper lenses 110, 110a, 110b, 110c, 210a, and 220a and the lower lenses 120, 120a, 120b, 120c, 210b, and 220b included in the illumination control modules 100, 100a, 100b, 100c, 200a, and 200b according to various example embodiments may have one surfaces formed in a convex shape and the other surfaces formed in a concave shape. In this case, considering the curvatures of both surfaces, the lenses may be classified into convex lenses and concave lenses. More specifically, when lenses have a positive (+) focal distance, they may be classified as convex lenses, and when lenses have a negative (−) focal distance, they may be classified as concave lenses.

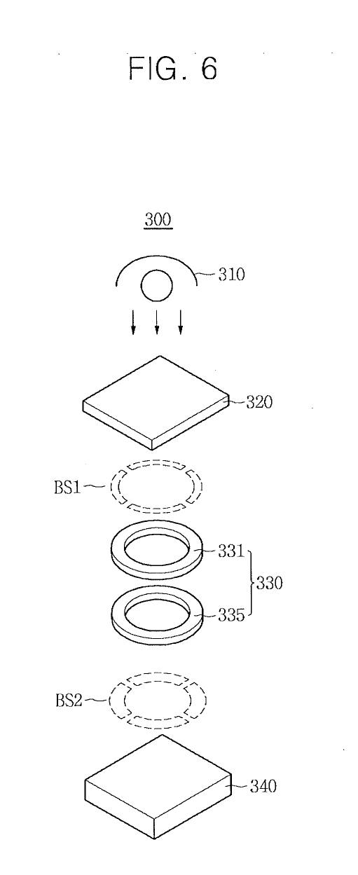

FIG. 6 is a diagram schematically illustrating a diffraction illumination system 300 and changes in beam shapes BS1 and BS2 according to an example embodiment. Referring to FIG. 6, the diffraction illumination system 300 according to this example embodiment includes a DOE 320 and an illumination control module 330. The diffraction illumination system 300 may further include a zoom system 340. Referring to FIG. 6, light generated from a light source 310 is irradiated onto the DOE 320. The light irradiated onto the DOE 320 is diffracted to form a first beam shape BS1. In this example embodiment, it is illustrated that the first beam shape BS1 is a cross-pole shape. The first beam shape BS1 is converted into a second beam shape BS2 by the illumination control module 330 according to this example embodiment. The second beam shape BS2 may have a different size from the first beam shape BS1. Further, light passing through a virtual plane of the second beam shape BS2 may have a different propagation angle from light passing through a virtual plane of the first beam shape BS1.

In general, the zoom system may be implemented as a combination of convex and concave lenses. In the diffraction illumination system according to this example embodiment, however, the illumination control module shown in FIG. 2 may be used as the zoom system.

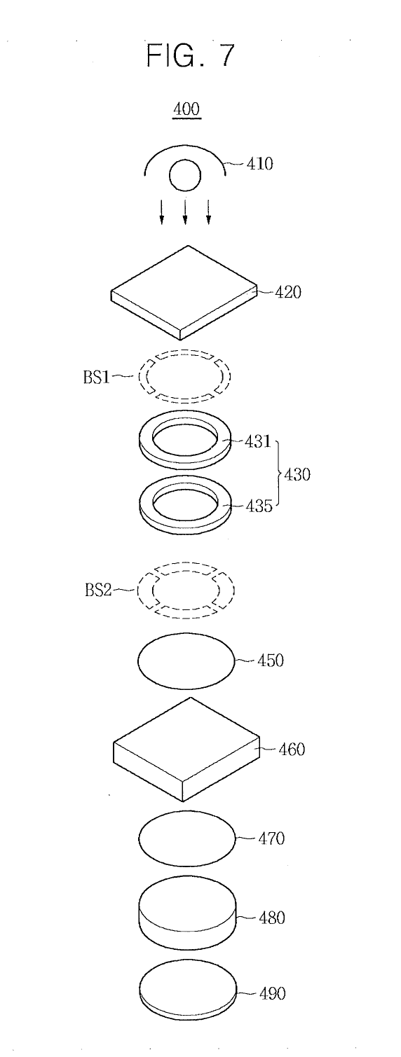

FIG. 7 is a schematic view of a photolithography system according to an example embodiment. Referring to FIG. 7, the photolithography system 400 according to this example embodiment includes a light source 410, a DOE 420, an illumination control module 430, a condenser lens 450, a photomask stage 460, a relay lens 470, a projection lens 480, and a wafer stage 490.

The light source 410 is a component which receives electric energy to generate light. As the light source 410, KrF, ArF and so on are known, and can generate various wavelengths of light. As a material used in the light source 410 is pure, the wavelength of light generated from the light source will be simplified. The light generated from the light source 410 is irradiated onto the DOE 420. The light irradiated onto the DOE 420 is diffracted by the DOE 420, and then converted into light having a first beam shape BS1 so as to be irradiated onto the illumination control module 430. The light irradiated onto the illumination control module 430 is converted into light having a second beam shape BS2, of which the propagation direction or illumination region is changed, and which is then irradiated onto the condenser lens 450. The condenser lens 450 serves to prevent the light from escaping outside. A plurality of condenser lenses 450 may be provided at various positions. FIG. 7 illustrates only one condenser lens 450 for the sake of the conceptual description. The photomask stage 460 is where a photomask is disposed if desired. To facilitate understanding, the photomask stage 460 is illustrated as a virtual photomask. Since the photomask is not a component which is necessarily included in the photolithography system 400, the photomask stage 460 is illustrated. The relay lens 470 serves to deliver the light to a next component. A plurality of relay lenses 470 may be provided at various positions, like the condenser lenses 450. The projection lens 480 may be disposed at the final position in the lens system included in the photolithography system 400. The projection lens 480 is a lens formed by combining a plurality of various lenses. The wafer stage 490 is where a wafer can be disposed. Since the wafer is not a component of the photolithography system 400 like the photomask, the wafer stage 490 is illustrated.

In this example embodiment, the first beam shape BS1 of the light having passed through the DOE 420 may be converted into various beam shapes (for example, the second beam shape BS2) by the illumination control module 430. The converted beam shapes can be properly applied to various photolithography processes.

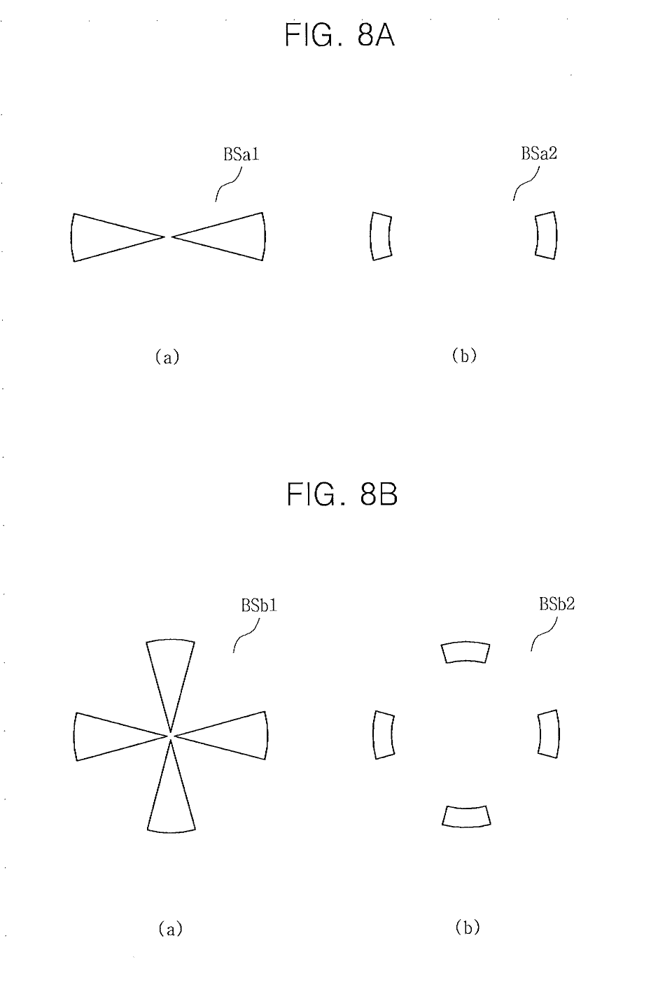

FIGS. 8A and 8B are diagrams for explaining beam shapes converted by the illumination control modules according to various example embodiments. Specifically, FIGS. 8A and 8B are diagrams for explaining that the first and second beams shapes may differ from each other in a state in which it is assumed that the above-described propagation angles and/or illumination regions of lights are identical. Referring to FIG. 8A, a first beam shape BSa1 formed in a dipole shape may be converted into a second beam shape BSa2 by, e.g., the illumination control modules 100, 200a, and 200b according to example embodiments.

Referring to FIG. 8B, a first beam shape BSb1 formed in a quadrupole or cross-pole shape is converted into a second beam shape BSb2 by, e.g., the illumination control modules 100, 200a, and 200b according to example embodiments.

In various example embodiments, the illumination control modules 100, 200a, and 200b include ring-shaped lenses. Therefore, the beam shapes formed by the illumination control modules 100, 200a, and 200b according to example embodiments may be basically annular. More specifically, when a virtual annular shape is superimposed on the original beam shape, that is, the second beam shape, the superimposed portion may be formed as the second beam shape.

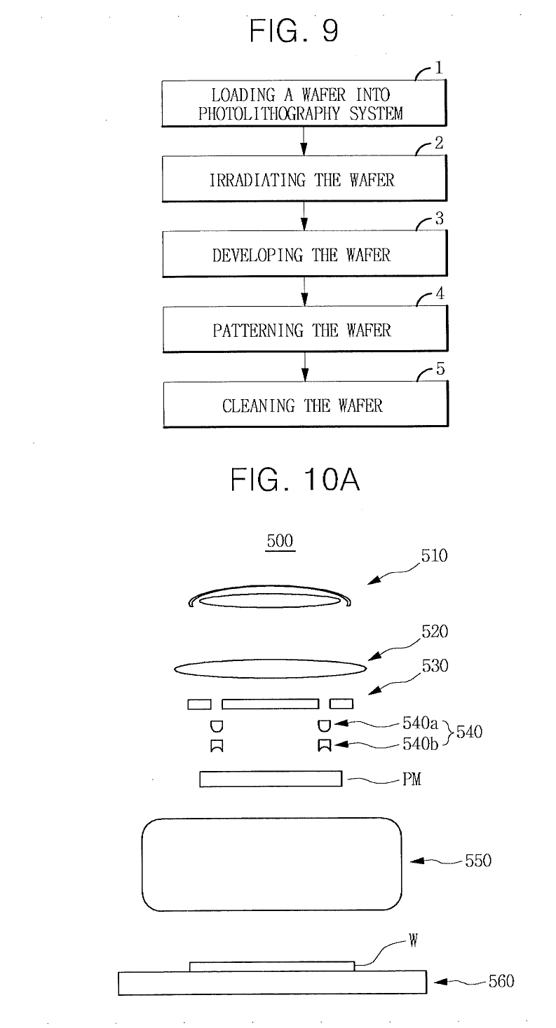

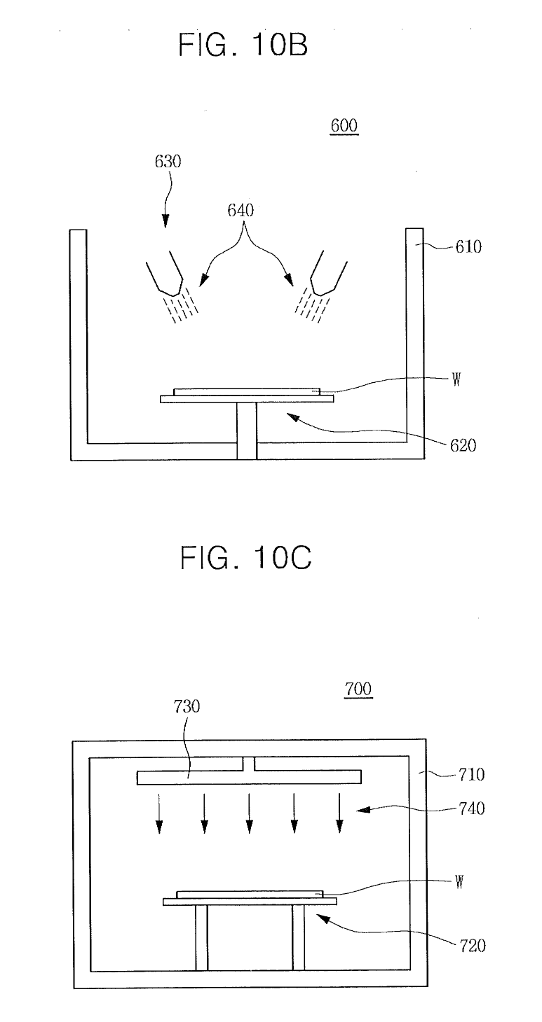

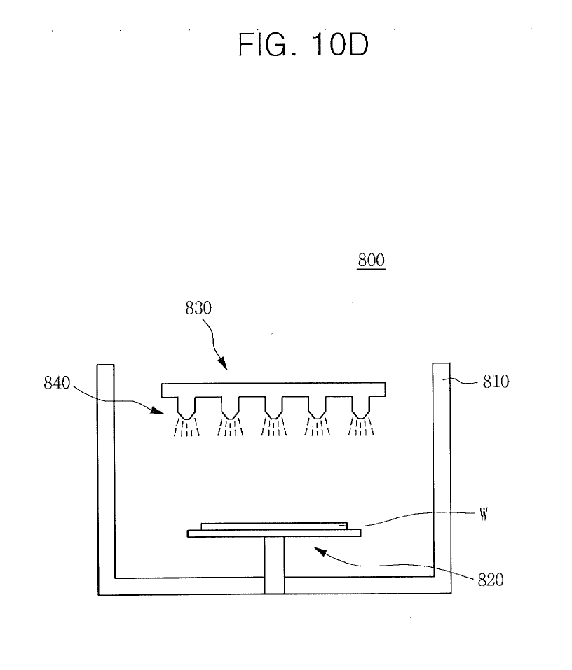

FIG. 9 is a flow chart illustrating steps of fabricating a semiconductor and FIGS. 10A to 10D illustrate processes of fabricating a semiconductor. Referring to FIGS. 9 and 10A, a wafer W may be loaded into a photolithography system 500 (1). The photolithography system 500 may include a light source 510, a condenser lens 520, a beam shaper 530, an illumination control module 540, a projection lens 550, and a wafer stage 560. The wafer W may be mounted on the wafer stage 560. The light source 510 may generate UV (ultra violet) light having a very short wavelength such as i-line, KrF or ArF. The condenser lens 520 may prevent loss of light deviating from the proper light path. The beam shaper 530 may be apertures defining shapes of light or beam. The beam shaper 530 is previously described. The illumination control module 540 may be one of the illumination control modules according to the inventive concept. The illumination control module 540 may include at least one convex-ring-shaped upper lens 540a and one concave-ring-shaped lower lens 540b. The photolithography system 500 may include a photomask PM. In other words, a photomask PM may be loaded in the photolithography system 500. The photomask PM may include optical patterns to be transferred onto the wafer W. The projection lens 550 may transfer the optical patterns from the photomask PM to the wafer W. The wafer W may include a photoresist layer on its own surface.

Again referring to the FIGS. 9 and 10A, UV light generated from the light source 510 may irradiate the wafer W by passing through the condenser lens 520, the beam shaper 530, the illumination control module 540, the photomask PM, and the projection lens 550 (2). The optical patterns of the photomask PM may be transferred onto the photoresist layer on the wafer W with scaling down.

Referring to the FIGS. 9 and 10B, the wafer W may be developed (3). More particularly, the photoresist layer of the wafer W may be developed using a chemical method and formed into a photoresist pattern. This wafer developing process may be carried out in a development apparatus 600. The development apparatus 600 may include a housing 610, a wafer supporter 620, and developing nozzles 630. The wafer supporter 620 may be able to spin. The developing nozzles 630 may spray developing chemicals 640 onto the wafer W.

Referring to FIGS. 9 and 10C, the wafer W may be patterned using the photoresist pattern as a patterning mask (4). Otherwise, any material layers between the photoresist pattern and the wafer W may be patterned. This patterning process may be carried out in a patterning apparatus 700. The patterning apparatus 700 may include a chamber 710, a wafer chuck 720 to mount the wafer W, and a gas supplier 730 supplying gases 740. The gases 740 may be excited to plasma.

Referring to FIGS. 9 and 10D, the photoresist pattern may be removed and cleaned in a cleaning apparatus 800 (5). The cleaning apparatus 800 may include a tub 810, a wafer mounting table 820, and cleaning nozzles 830. The cleaning nozzles 830 may spray rinse chemicals and/or water 840 onto the wafer W. Then, semiconductors may be fabricated using the illumination control module, the diffraction illumination system, and/or the photolithograph system.

A photolithography system including an illumination control system according to the example embodiment can apply one DOE to various photolithography processes. Therefore, it is possible to increase productivity and decrease production costs.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1-10. (canceled)

11. A method of fabricating a semiconductor, comprising:
loading a wafer into a photolithography system, the wafer having a material layer and a photoresist layer thereon,
irradiating the photoresist layer using UV light,
developing the photoresist layer to form a photoresist pattern,
patterning the material layer to form a material pattern using the photoresist pattern as a patterning mask,
removing the photoresist pattern, and
cleaning the wafer,
wherein the photolithography system comprises:
a convex ring-shaped upper lens; and
a concave ring-shaped lower lens coaxial with the upper lens along the axis of light incident to the upper lens.

12. The method of fabricating a semiconductor according to claim 11, wherein an absolute value of a focal distance of the lower lens is different from that of the upper lens.

13. The method of fabricating a semiconductor according to claim 12, wherein the absolute value of the focal distance of the lower lens is greater than that of the upper lens.

14. The method of fabricating a semiconductor according to claim 11, wherein the upper and lower lenses move in a vertical direction independently from each other.

15. The method of fabricating a semiconductor according to claim 11, wherein the upper and lower lenses have the same circular constant.

16. The method of fabricating a semiconductor according to claim 11, wherein a horizontal width of the upper lens is larger than that of the lower lens.

17. A method of fabricating a semiconductor, comprising:
loading a wafer into a photolithography system, the wafer having a material layer and a photoresist layer thereon,
irradiating the photoresist layer using UV light,
developing the photoresist layer to form a photoresist pattern,
patterning the material layer to form a material pattern using the photoresist pattern as a patterning mask,
removing the photoresist pattern, and
cleaning the wafer,
wherein the photolithography system comprises a diffraction illumination system having a diffraction optical element and an illumination control module, the illumination control module comprising:
a convex ring-shaped upper lens; and
a concave ring-shaped lower lens coaxial with the upper lens along the axis of light incident to the upper lens.

18. The method of fabricating a semiconductor according to claim 17, wherein a first beam shape is formed by the diffraction optical element, and converted into a second beam shape different from the first beam shape by the illumination control module.

19. A method of fabricating a semiconductor, comprising:
loading a wafer into a photolithography system, the wafer having a material layer and a photoresist layer thereon,
irradiating the photoresist layer using UV light,
developing the photoresist layer to form a photoresist pattern,
patterning the material layer to form a material pattern using the photoresist pattern as a patterning mask,
removing the photoresist pattern, and
cleaning the wafer,
wherein the photolithography system comprises a light source, a diffraction optical element, an illumination control module, a condenser lens, a photomask stage, a relay lens, and a wafer stage,
wherein the illumination control module comprises:
a convex ring-shaped upper lens; and
a concave ring-shaped lower lens coaxial with the upper lens along the axis of light incident to the upper lens.

20. The method of fabricating a semiconductor according to claim 11, the photolithography system further comprising a zoom system.
